(19) United States
(12) Patent Application Publication
(10) Pub. No.: US 2011/0134947 A1
(43) Pub. Date: Jun. 9, 2011

(54) LASER ASSEMBLY AND METHOD AND SYSTEM FOR ITS OPERATION

(75) Inventors: Uzi Rahum, Beer-Sheva (IL); Meir Aloni, Herzelia (IL); Eran Brand, Tel Mond (IL); Gil Shpak, Herzliya (IL)

(73) Assignee: X.D.M. LTD., HERZLIYA (IL)

(21) Appl. No.: 13/058,467

(22) PCT Filed: Aug. 11, 2009
(86) PCT No.: PCT/IL2009/000784

§ 371 Date: Feb. 10, 2011

Related U.S. Application Data
(60) Provisional application No. 61/087,756, filed on Aug. 11, 2008.

(51) Int. Cl. H01S 5/068

(52) U.S. Cl. 372/29.015

(57) ABSTRACT

A laser assembly and a method for controlling light output thereof are presented. The laser assembly comprises a semiconductor laser diode having an active region and its associated electric current driver. The electric current driver is controllably operated to excite said active region to induce a certain electric current profile therethrough. The electric current profile corresponds to a desired emission profile from the laser assembly and a desired over heating profile of the active region of the laser diode, while maintaining predetermined temperature range of said active region of the semiconductor laser diode.

### FIELD OF THE INVENTION

This invention is generally in the field of lasers, and relates to a laser assembly and a method and system for operating the laser assembly, aimed at improving the laser output. The invention is particularly useful for semiconductor laser diodes, Diode Pumped Solid State Laser (DPSS) structures and direct-doubling lasers.

### BACKGROUND

Semiconductor laser diodes are usually driven by electric current. However, for a given electric current, the output of such laser diodes (the optical power and the radiation wavelength) is strongly dependent on the device temperature. In order to provide the desired output of the laser diode, controlling of the laser diode temperature during the operation is thus used.

Semiconductor laser diodes are often used as pump lasers. For example, a DPSS laser structure includes a pump laser diode (or diode array) and a laser crystal (gain medium) to deliver a highly stable wavelength output. The pump laser diodes generate light with high efficiency at a wavelength that matches the absorption spectrum of the laser crystal. Additional crystals can also be accommodated in the DPSS laser cavity. This feature generates emissions in the visible, blue, NIR and UV parts of the spectrum.

The DPSS laser's optical efficiency is highly dependent on the overlap of the pumping light spectrum and the gain medium absorption spectrum, and also on the pumping light power density. According to the conventional techniques, the spectra overlap is achieved by controlling the pump laser diode temperature, using Thermo Electric Cooler (TEC) or other external heaters and fans. A passive method to keep the laser in the proper temperature range is by using a heat sink that has enough surface area to dissipate the generated heat out of the system.

WO 2008/054993 discloses a laser system such as a DPSS green laser. The laser system uses a laser diode pump source that is specially selected so that the wavelength of diode source is centered around the optimal source wavelength, typically 808 nm, which produces the optimal green laser output from the system. Unlike prior systems in which the source wavelength is at 808 nm at typical ambient temperature of about 25° C., in the system disclosed, the source wavelength is at 808 nm at a temperature significantly higher than ambient, which may be as high as about 50° C. In this system optimum performance can be established and maintained in a broad temperature range such as 0-50° C. using only a heating element adjacent to the diode laser pump source. No cooling is required. Cost, size, and power requirements of the system are therefore minimized.

### GENERAL DESCRIPTION

There is a need in the art in high-efficiency and small and light laser diode based lasers, for example for use in portable electronic devices, such as but not limited to micro-projectors. Mini devices need to be operated by limited electrical power source such as batteries, and accordingly high power consumption components such as active cooling technologies are practically not acceptable.

Projection devices are widely used for displaying video and other graphical information. Common projection device use a spatial light modulator (SLM), such as Liquid Crystal Display (LCD), DLP, MMD, DMD or LCOS panel, and primary colors light sources, Red, Green and Blue (RGB), modulated to display the electronics signals as proper lighted picture. The picture is enlarged and projected on a distant surface by a projection lens.

LEDs, VCSELS, Green Laser diodes and DPSS lasers are few approaches to deliver RGB light for the RGB projectors. DPSS lasers radiate at a discreet wavelength by introducing to the lasing gain medium light at it's pumping absorption spectra and optical power higher than the lasing threshold.

The present invention provides for controlling the spectrum and power of a semiconductor laser diode (e.g. used in a pump laser diode) via controlling the temperature of its active region (junction). This is achieved by locally heating the active region (laser junction) from ambient temperature to its operational temperature. The latter is that under which the active region can be excited (by an electrical signal of a value higher than certain threshold) to emit light of required power and spectrum. This technique is highly efficient since the heat is created directly in the emitter area.

Thus, according to one aspect of the invention, there is provided a method for controlling light output of a laser assembly, which comprises a semiconductor laser diode having an active region and its associated electric current driver, the method comprising controllably operating said electric current driver to excite said active region to induce a certain electric current profile therethrough, said electric current profile corresponding to a desired emission profile from the laser assembly and a desired over heating profile of said active region, while maintaining predetermined temperature range of said active region of the semiconductor laser diode.

The required output of the laser assembly is dependent on the required power and spectrum of the semiconductor laser diode.

In some embodiments of the invention, over heating is applied to the active region during the emission, such that the electric current profile corresponds to a pulse mode emission profile and a continuous heating profile. In some other embodiments of the invention, over heating is applied to the active region in between emission sessions, the electric current profile corresponding to interlaced pulse mode emission and heating profiles. The emission pulse might have a burst pulse profile.

Typically, the emission of a required power and a required wavelength range from the active region is achieved by exciting the active region with an electrical signal of a value above certain working threshold of the laser assembly. The working threshold of the laser assembly may be a lasing threshold of the laser diode, or may be a pumping threshold of an emitter being pumped by said laser diode. In some embodiments of the invention, the electrical signal supplied to the active region is of a value above the certain working threshold of the laser assembly and below a certain nominal threshold of the laser assembly (e.g. nominal level of gain medium pumped by the laser diode).

Preferably, either the laser diode is selected or the initial properties of a given laser diode are set such that an optimal operating temperature of the active region, at which the laser diode has required output, is higher than ambient temperature or thermal steady state temperature.

The laser diode may be a pumping laser for pumping an external emitter. For example, such external emitter includes a resonator cavity, e.g. including a gain medium and a frequency converter crystal operated by light output of the gain medium. The temperature range of the pumping laser is maintained to produce the wavelength output of the pumping laser corresponding to a maximal absorption of the gain medium. For example the laser assembly of the invention is configured for producing output of about 808 nm or 880 nm (green laser).

Preferably, a desired alignment between the laser diode and the resonator cavity is provided. For example, the laser diode and the resonator cavity are mounted such that at least one of the laser diode and the resonator cavity is movable with respect to the other along an optical axis of the laser assembly and rotatable about said optical axis.

Preferably, the resonator cavity is configures such that substantially symmetrical heat dissipation therefrom is provided.

According to another broad aspect of the invention, there is provided a method for controlling light output of a laser assembly, the method comprising: (i) selecting a semiconductor laser diode having an active region capable of emitting a required spectrum under a certain operating temperature of the active region higher than ambient temperature of environment in which the laser assembly is installed, (ii) controllably operating said electric current driver to excite said active region to induce a certain electric current profile therethrough corresponding to a desired emission profile from the laser assembly and a desired over heating profile of the active region, while maintaining predetermined temperature range of said active region of the semiconductor laser diode.

According to yet another broad aspect of the invention, there is provided a laser assembly comprising:

a semiconductor laser diode having an active region excitable by an electric current supplied from an associated electric driver for providing emission of light of a required power and spectrum from the laser assembly under a certain operating temperature range of the active region of the laser diode higher than ambient temperature of the laser assembly; and

an excitation utility connectable to said electrical driver and configured and operable for generating an electrical signal corresponding to a certain electric current profile providing a desired emission profile from the laser assembly and a desired over heating profile of the active region, while maintaining predetermined temperature range of said active region of the semiconductor laser diode.

More specifically, the present invention is used with a DPSS laser structure and is therefore exemplified below with respect to this specific application. It should however be noted that the invention is not limited to this specific example, and can be used with any semiconductor laser diode.

### DETAILED DESCRIPTION OF THE EMBODIMENTS

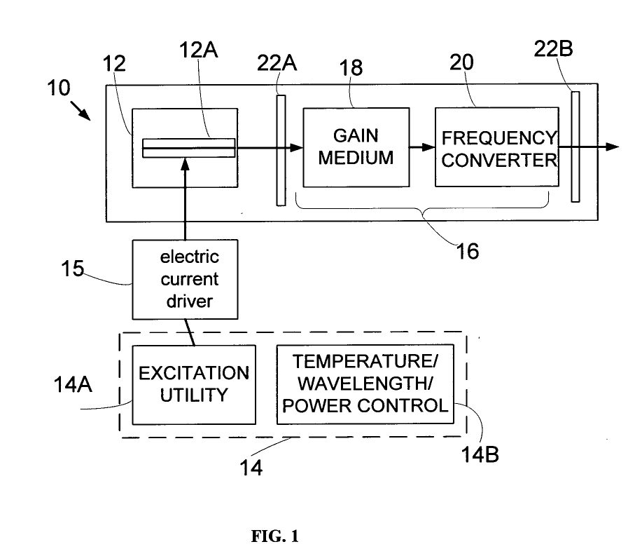

Referring to FIG. 1, there is schematically illustrated an example of a laser assembly 10 utilizing the principles of the present invention. The laser assembly 10 includes a semiconductor laser diode 12, having an active region 12A (laser junction), and being associated with (connectable to) an electric current driver 15 operable to apply electric current to the active region 12A to thereby enable the emission therefrom. In the present not limiting example, laser assembly 10 is configured similar to a DPSS laser structure, where laser diode 12 serves as a pumping laser and is used in combination with a resonator cavity 16, which in this example includes a gain medium 18 and a frequency converter (non-linear crystal) 20 between two light couplers (reflectors) 22A and 22B.

In the present example, frequency converter 20 is an intracavity element, but it should be understood that it may be located outside the resonator cavity. Reflectors 20A and 20B may be constituted by input and output facets of the gain medium unit or the gain/converter unit. Also, in the present not limiting example, laser diode 12 is associated with a laser cavity 16, including gain medium 18 and frequency doubler 20, e.g. being for example a green laser assembly.

It should also be noted that the invention is limited neither to DPSS nor any other specific configuration of a laser diode assembly. Generally, laser assembly 10 may include a laser diode, a coupling optics, a photo detector, a laser diode and one or more crystals, etc. Considering the illustration in FIG. 1, laser diode with which the invention may be used may be constituted by pumping laser 12 and/or “gain medium” crystal 18.

The resonator cavity may include appropriate resonator optics designed to form a resonator with a laser spot of a required size that will properly deliver optical pumping power density. Gain medium typically contains some atoms, ions or molecules in an initially excited state, which can be further excited/stimulated by the induced pumping light to emit more light into the same radiation modes. As for the frequency converter, if any, it includes a non linear medium (crystal) that exhibits optical non-linearity frequency conversions, i.e. high harmonic generation.

In the present example, the resonator cavity 16 includes the gain medium (crystal) 18 and the second harmonic generation (SHG) crystal 20. They are bonded to create one unit, the two facets of which are used as two Plano resonator mirrors (input and output couplers 22A and 22B). The gain medium may for example include Neodymium or Gadolinium based crystals such as Nd:YVO₄; Gd:YVO₄; Nd:YAG; Nd:YLF. Those crystals are pumped by ˜809 nm or ˜880 nm laser diode 12 and their stimulated emission (lasing wavelength) radiate at 1064 nm. As for the non-linear crystal 20, for a green laser (532 nm) for example it is required to double the gain medium wavelength, which can be achieved by using SHG non linear crystals such as KTP, BBO or PPLN. Considering a micro-projector, the resonator cavity 16 (formed by gain medium 18 and Doubling crystal 20) should be as short as possible, thus being of the Plano-Plano configuration. Geometrically it's a Plano Plano resonator. Effectively however, due to thermal lensing, the resonator can act as either one of a Plano-Plano, Plano-convex or convex-convex configurations.

It should be noted that the DPSS laser structure may also include Q-switch elements, such as passively saturable absorber or acoustic q-switching, and/or coupling optics between the pumping laser diode and the gain medium.

The present invention can for example be used as a light source unit, e.g. high power mini-DPSS green laser, in a projection system.

The DPSS laser optical-to-optical efficiency is highly dependent on the overlap of the pumping light wavelength and the gain medium absorption spectrum, and also dependent on the pumping light power density. As indicated above, the wavelength (and possibly also optical power) of the pumping light are strongly dependent on the operating temperature of the active region of the laser diode, which in turn depends on the ambient temperature of the laser diode. While the gain medium absorption spectrum is not influenced at all or is less influenced by a change of the ambient temperature, the pumping laser central wavelength shifts typically by ˜0.3 nm/° C., and hence affects the pumping efficiency.

The laser diode 12 central wavelength and wavelength spectrum are dependent upon the temperature of its emitter junction or active region 12A. The emitter junction temperature is determined by the diode operation conditions such as ambient temperature (Ta), driving current, operating voltage, wavelength drift Δλ/ΔT and the “on/off” durations (duty cycle and frequency).

The invention provides for controlling the laser diode output (i.e. wavelength), pumping laser diode in the present not limiting example, via controlling its emitter junction temperature. To this end, optimal operation of the laser diode should be provided until the laser diode reaches its steady state operation conditions (warm up time); and the laser diode optical output properties (wavelength and power) should be controlled independently on surrounding temperature fluctuations. As indicated above, the laser diode wavelength is controlled by locally heating of the laser junction region. This method is highly efficient since the heat is created directly in the emitter area.

Some lasers are characterized by having very low wavelength drift over a certain temp range (i.e. Stabilized wavelength lasers such DFB/DBR lasers), however this special character only holds for a certain temperature range. The same technique of the local heating of the active region of the laser using the laser driver/electric current supply (controlled via the excitation utility) can be used to keep that laser module within its special optical characteristic window.

By knowing the laser properties and the laser operating conditions one can estimate the initial wavelength of the laser diode (usually determined by the vendor for continuous wavelength (CW) operation at 25° C.).

For example, for optimal operation of a 809 nm pumping laser diode at 55° C. and Δλ/ΔT=0.3 nm/° C., the wavelength (at 25° C.) will be determined by:

809 nm−(55−25)×0.3 nm=800 nm

Obviously, this number will be affected by the operating conditions and other laser properties.

The semiconductor laser diode is characterized by a lasing threshold, above which emission from its active region (laser junction) occurs, and below which laser emission does not occur, namely corresponds to a minimal electrical power that the semiconductor requires to radiate as a laser (and not as a LED). For the purposes of the present application, the laser assembly is characterized by a certain working threshold below which the electric current through the active region does not provide effective emission from the laser assembly but is mainly used to generate heat. Thus, this working threshold may coincide with a lasing threshold of the lasing diode being the characteristic of the laser diode itself. In case where such laser diode is used as a pumping laser, e.g. DPSS laser, for pumping an external emitter (e.g. crystal, gain medium), the working threshold of the laser assembly corresponds to a pumping threshold of the external emitter, and is higher than the lasing threshold. Such pumping threshold relates to emission properties of the external emitter (crystal, gain medium), at which the emitter (gain medium), pumped by the laser diode, starts emission.

Generally when increasing the electric current above the working threshold the energy contributing to the heat increases as well. Thus there might be a certain nominal threshold of the laser assembly (which is typically the case when using the gain medium as external emitter in the laser assembly) above which an increase in the electric current supply to the active region provides some increase of emission and heat to the junction in a certain efficiency and thus excess current supply contributes to the local heating of the active region of the laser diode and or of the emitter (gain).

The present invention utilizes local heating of the laser diode within its active region during time slots in between at least some of the emission sessions and/or during at least some of the emission sessions. This local heating is carried out using an electrical signal of a kind used for activating the laser diode to emit light.

As shown in FIG. 1, laser assembly 10 is associated with a control unit 14. The control unit 14 includes an excitation utility 14A, which is an electrical circuit configured and operable for applying an electrical signal to active region 12A of the laser diode 12. Such excitation utility 14A operates the emission function of the laser assembly 12 (pumping diode in the present example), i.e. a desired emission time profile, e.g. pulse mode with a predetermined duty cycle and current. In this connection, it should be noted that for the case of direct doubling laser utilizing a frequency doubler, the conventional techniques take special care about maintaining the output wavelength of the gain medium within a very precise narrow range of values to suit the input frequency of the doubler (corresponding to the optimal efficiency of the doubler) and thus ensure the required wavelength output of the cavity 20. According to the invention, the same excitation assembly 14A is used for local electrical heating of the active region 12A of the pumping laser to maintain the active region 12A at a desired temperature range.

Semiconductor laser diode 12 is selected such that its active region 12A is excitable to emit light of a required power and spectrum under a certain operating temperature of the active region 12A, where this operating temperature is higher than ambient temperature of the laser assembly 10 (i.e. higher than the temperature of the entire laser assembly 10). This is achieved by “over” heating of the active region 12A during the operation of the laser diode 12. According to the invention, both the generation of the required emission profile and the provision of the desired temperature of the active region, are implemented by the excitation utility 14A.

To this end, the control unit 14 (excitation utility 14A) operates to generate a modulated electrical signal of a certain predetermined profile for managing both the emission from and the local heating of the active region (junction) 12A. In this connection it should be noted that the electric current provided to the active region is selectively in one of three main regimes, as follows:

In the first regime, the electric signal is below the working threshold of the laser assembly (e.g. being the lasing threshold of the active region 12A or in this specific example being the pumping threshold of the gain media 18). Such electric signal may be above the lasing threshold of laser diode 12 but below the pumping threshold of the gain 18. In this regime, heating effect of the active region is much higher than the emission from the laser assembly. In other words the heating efficiency is highest as substantially all of the electrical power is converted to heat.

In the second regime, the electric current is above the working threshold of the laser assembly (i.e. lasing threshold of the laser diode 12 or in this specific example the pumping threshold of the gain). In this regime, the electric signal generally causes both the emission from the laser assembly and heating of the active region. However, as long as the electric signal is below the nominal threshold if any, an increase in the electric signal affects the emission, and also contributes to the heating. Also, in this regime, when the electric signal becomes above the nominal threshold, it substantially affects the emission and contributes to the heating of the active region.

Accordingly, controlling the wavelength of the laser assembly can be achieved by controlling the temperature of its active region using various operational modes of the excitation utility so as to operate the active region 12A in different modes. In the case of the laser diode in which the emission effect is achieved by using a pulse emission with a certain duty cycle, proper heating of the active region can be achieved with either one of the following operational modes: providing over heating of the active region in between the emission sessions of the laser assembly (interlaced pulses of the emission and over heating), or providing overheating of the active region in between and during the emission of the laser assembly.

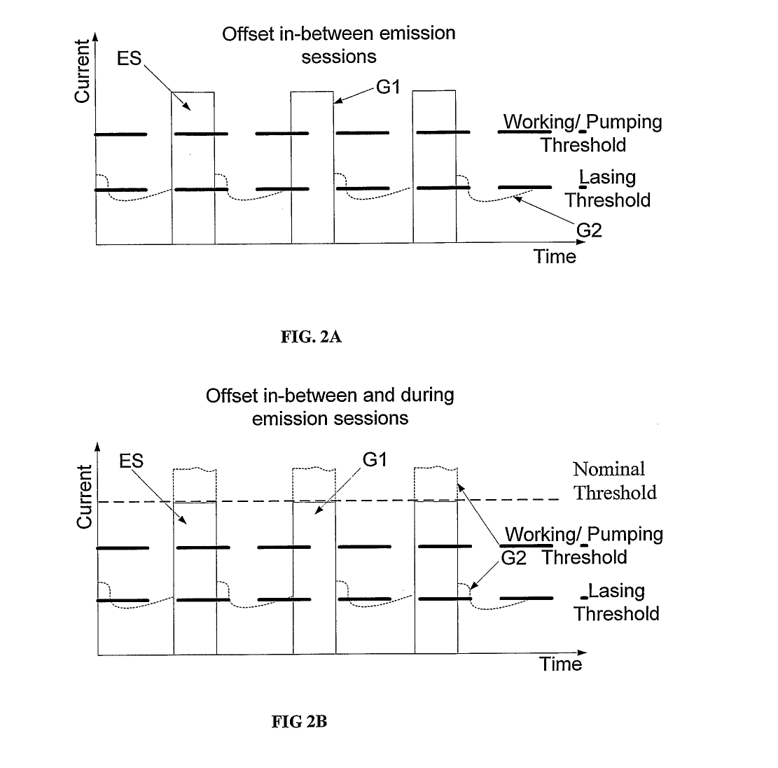

Referring to FIGS. 2A and 2B, there is graphically exemplified the modulated electrical signal generated by the excitation utility and supplied to the active region 12A of the laser diode. Both figures correspond to the laser diode operable with a certain duty cycle, where the electrical signal is modulated to achieve, concurrently with the emission cycle, the local over heating of the active region. Each of the figures illustrates a profile G₁ of the emission current (i.e. electric current through the active region causing emission therefrom) in the form of a sequence of pulses, and a profile G₂ of the total current through the active region being a sum of the emission current and the heating current.

In the example of FIG. 2A, the excitation utility operates with a combination of the first and second regimes, such that the over heating takes place in between the emission pulses. In this case, during the time periods in between the emission sessions, electric current G₁ through the active region of the laser diode is above zero but below the working threshold (which is constituted by the pumping threshold in the present example), thereby providing heating of the active region at these time periods while not allowing emission from the laser assembly. During the emission session, the electric current corresponds to a nominal operation mode of the laser diode, at which the electric current reaches a value above the working threshold and thus actually effects both the emission and heating.

The example of FIG. 2B corresponds to a combination of the first and second regimes, such that the over heating takes place both during the emission sessions and in between the emission sessions. Here, during the time periods between the emission sessions, the electric current is above zero but below the working threshold, similar to that of the example of FIG. 2A, and during the emission sessions the electric current reaches a value above the working threshold such as to cause over heating of the active region, i.e. being above the nominal value. In this specific example the electric current during the emission sessions is above the nominal threshold.

It is important to note that it is possible to cause heating of the laser junction, between the emission sessions, by driving a current which is above the working threshold, and below the nominal threshold, at a level which does not substantially compromise the system level requirement.

It should be understood that the technique of the present invention appropriately manipulates the “total” efficiency of the laser diode, i.e. defined by a ratio or an average ratio of the output lasing power and the electrical input power. As can be seen from FIGS. 2A and 2B, such manipulation can be achieved by providing an appropriate profile of the electric current through the active region. Moreover, the manipulation takes into account the output power profile of a laser assembly during the emission session.

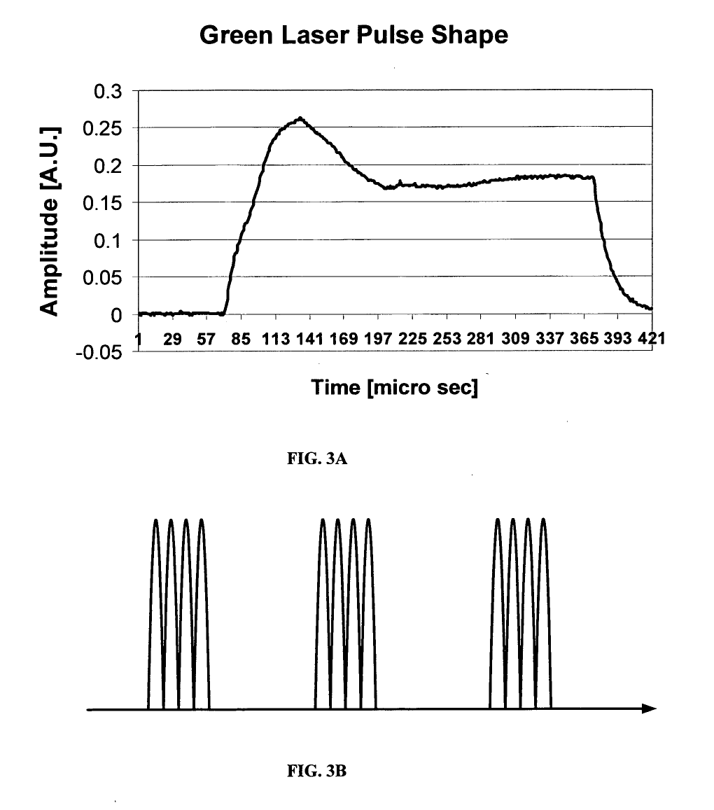

In this connection, reference is made to FIG. 3A showing a typical laser pulse shape. As can be seen, the optical output power of the pulse is not constant with time: the first part of the pulse has higher optical power, which part of the pulse has typical time constant followed by a lower emission power. To get better electrical-to-optical efficiency of such laser, the emission session can be split into several sub-pulses (bursts). This is schematically illustrated in FIG. 3B.

Turning back to FIG. 1, it is shown that the control unit 14 preferably also includes a controller 14B for monitoring one or more parameters of the laser diode 12A, such as operating temperature and/or output wavelength and/or output power, and generating a control signal to be used for operating the excitation utility accordingly. To this end, the laser assembly may include a detection/measurement unit operable continuously or periodically (e.g. being actuated by controller 14B) for taking measurements of said one or more parameters/conditions of the laser diode 12 operation. For example, the laser diode unit 12 includes an appropriate indicator/sensor (not shown), for example Thermistor, NTC, PTC, TC, VIS/IR optical detector or photodiode.

As described above, for effective operation of the laser assembly 10, i.e. to provide required output (spectrum and power), the pumping light spectrum at the output of the laser diode 12 should include a wavelength range of exciting spectra of the gain medium 18 and the optical power at the laser diode output should be above a predetermined lasing threshold for said gain medium. On the other hand, in order to emit pumping light of the required spectrum and power, the operating temperature of the laser diode during emission sessions should be of a certain predetermined value or range of values. This is achieved by appropriate selection of the laser diode and controlling the operating temperature, as described above.

Considering a DPSS laser structure, it is typically operated in a duty cycle mode, having two main operating states: “On” state in which the optical power is defined by the optical power control system requirements, and “Off” state in which the optical power is low enough not to deteriorate system performance. In some embodiments of the invention, the junction (active region) temperature (and thus output wavelength) can be controlled by providing electrical power to the laser diode at its “off” state (in between emission sessions). Moreover, when a laser diode is operated below the lasing threshold, where the electrical-to-optical conversion efficiency is lower, the thermal heating efficiency of the junction is higher.

The electrical current at off state can be applied at different configurations:

(a) Variable electrical current, of a value varying between 0 Amper to the current that will deteriorate system performance can be applied to the active region.

(b) Electrical current of a fixed profile can be applied in the form of a pulse train. In this case, the total heat injected is determined by the pulse number, width and amplitude.

(c) Electrical current of a fixed profile can be applied in the form of PWM, in which case the total heat injected is determined by the pulse width.

The pulses of electrical current at off state power can be applied at different time periods, relative to the on state time period.

An example of a typical DPSS laser is a laser assembly including a pumping laser with a lasing threshold of 0.5 A at a voltage of 2V and a gain-medium pumping threshold of 500 mW of the pumping laser power. There are two options for local heating the active lasing region of the pumping laser, using the method of the present invention:

(1) The pumping laser is driven under the lasing threshold. In that case, assuming the electrical-to-optical efficiency is 40%, then the induced heat to the laser junction is about (1−0.4)×0.5 A×2V=0.6 W. For an “on” duty cycle of 33%, the heat load will be 0.67×0.6 W˜0.4 W.

(2) The pumping laser is operated under the pumping threshold. Driving the pumping laser above the lasing threshold (in the laser mode) but when its output optical power is still under the pumping threshold of 500 mW (assuming that for 809 nm, a driving current of 0.8 A, 2V is needed), would result in that the active region will have a thermal load of 0.8 W. For an “on” duty cycle of 33%, the heat load will be 0.80×0.67 W˜0.54 W.

The junction (active region) temperature (and thus output wavelength) can also be controlled by changing the electrical power to the laser diode at its “on” state. As indicated above, the power at on state can be applied at different configurations: increasing/decreasing the current at on state (operating with second or third regime); or modulating the current at high modulation speed (burst-mode emission).

Thus, the invented method allows for controlling the semiconductor laser diode wavelength by injecting electrical power during the laser diode operation to locally heat the active region (emitting region) and control the active region (junction) temperature. As indicated above, semiconductor laser diode may be a pumping laser used with a gain medium unit, in which case the output spectrum of the laser diode is included in the gain medium high absorption spectrum. The semiconductor laser diode may be heated while being at “off” state in between “on” state sessions and possibly also at “on” state sessions. The laser assembly preferably utilizes a temperature indicator (and/or wavelength and/or power control) associated with the laser diode, and a closed or open loop control (communication between controller 14B and excitation utility 14A in FIG. 1) to appropriately apply the local heating. The laser diode at “off” state may be operated differently at warm up transient time and at steady state. The use of local heating of the active region using the laser diode driver allows for increasing the operating temperature range of the laser diode, e.g. up to 40°, thereby providing the laser diode less sensitive to changes in the ambient temperature conditions.

The above described control of the output spectrum of a laser diode by locally heating the active region thereof can be used in the DPSS laser operation as well as direct-doubling lasers; in order to decrease the laser warm up time to steady state operation; to control the semiconductor laser diode optical properties, in laser chip and the emitter heating.

Considering the use of a laser assembly where a semiconductor laser diode serves as a pumping laser for gain medium, the laser diode and the gain medium should preferably be appropriately aligned in order to achieve the optimum efficiency and power. This is for example needed to meet a requirement for polarization output of the laser assembly, for example where the laser assembly is used with a spatial light modulator (SLM). Thus, assembling the laser diode and the gain medium together might require a certain alignment procedure. An example of such alignment procedure is described below.

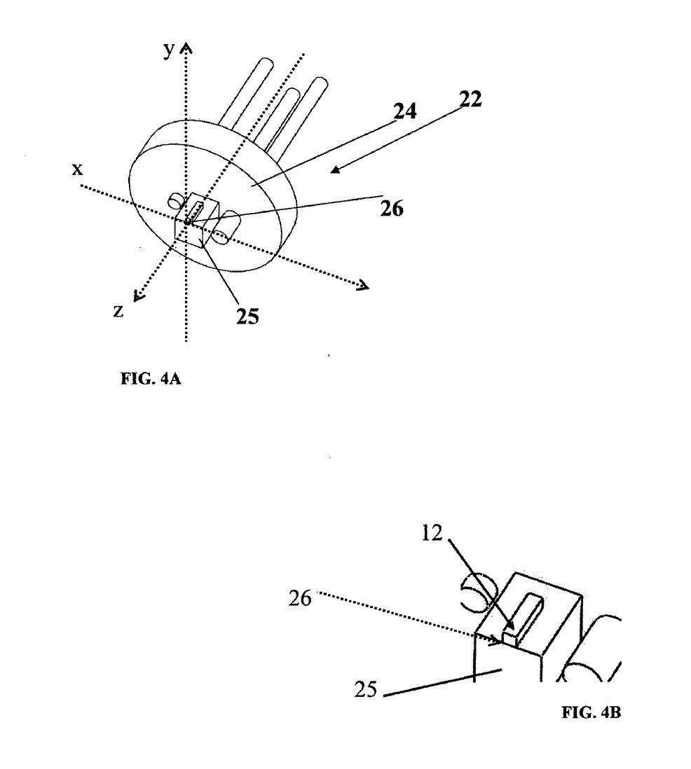

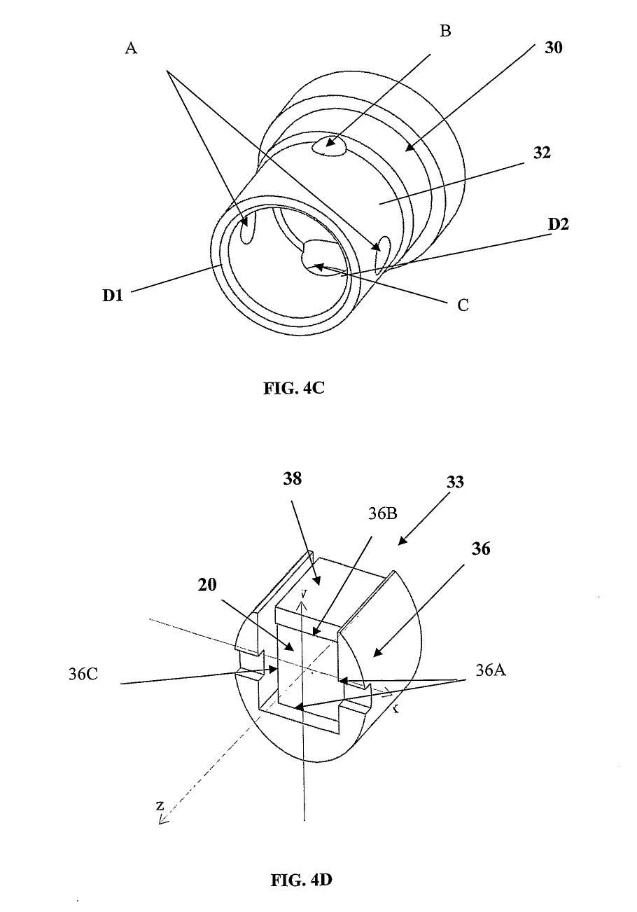

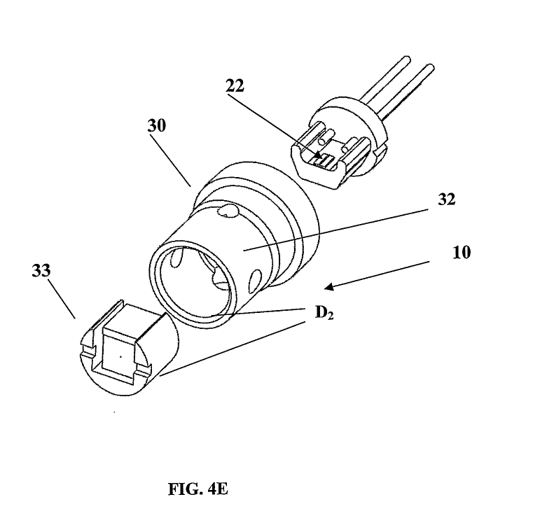

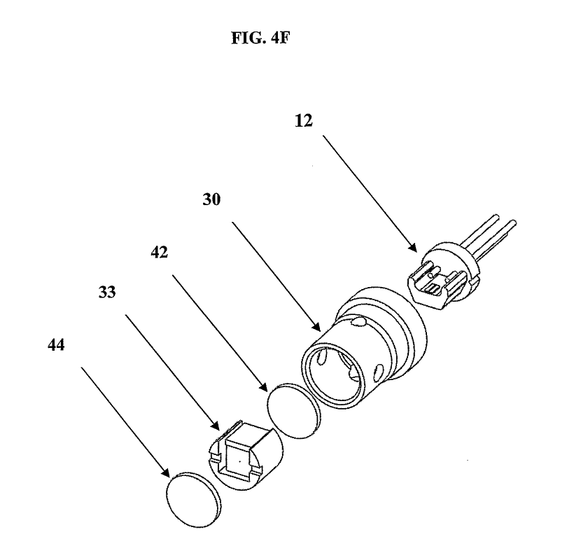

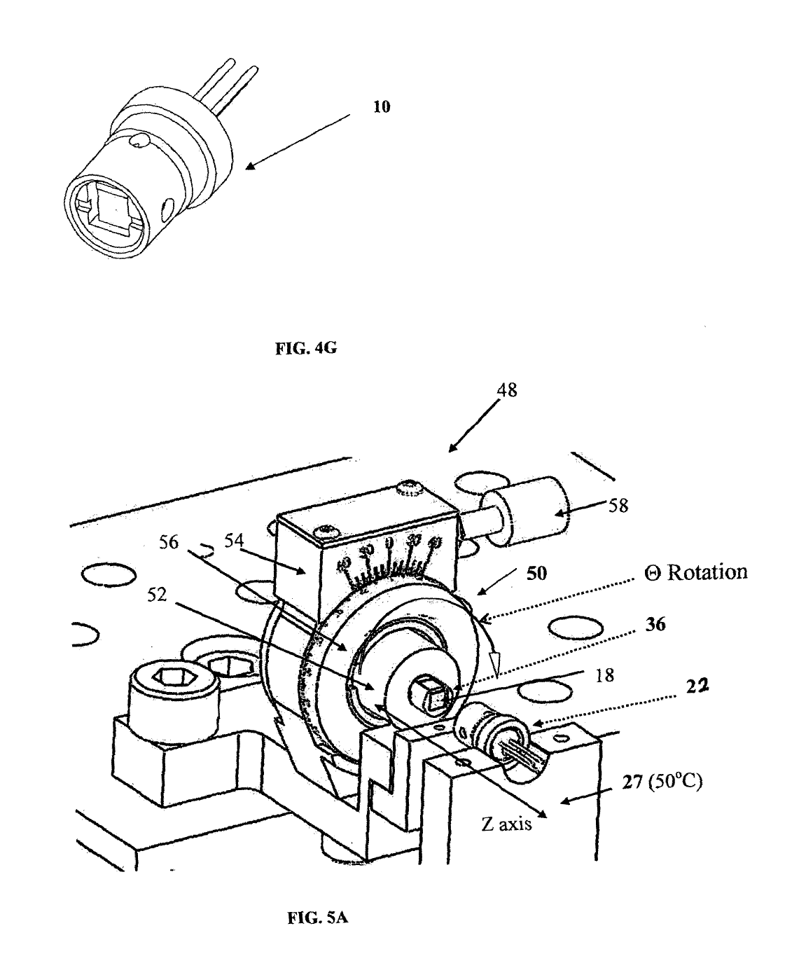

Reference is made to FIGS. 4A-4G showing more specifically an example of the configuration of the laser assembly 10 operable as a green laser assembly. To facilitate understanding the components common in all the examples are identified by the same reference numbers. As indicated above, such laser assembly 10 includes a pumping laser diode 12 and a resonator cavity 16 including a gain medium (crystal) 18 and/or frequency converter (crystal) 20.

FIGS. 4A and 4B show a laser diode unit 22 which includes laser diode 12 mounted on a package 24 (FIG. 4A). The laser diode 12 is placed on a heat sink 25, and has a facet 26 through which emitted light outputs the laser diode. The facet 26 is located in the X-Y plane and is oriented to be orthogonal to an optical axis Z of the laser assembly. A pumping laser diode can be located in a housing that serves as a heat sink, and it is necessary that the thermal resistance between the laser diode and the housing is the lowest. The laser diode housing can also serve as the full laser assembly where all the laser components are set in (such as laser diode, coupling optics, crystals, beam splitter, optical detector and optical window). Such housing may be mounted in a temperature controlled holder that keeps the laser diode at a temperature that mimics the laser assembly temperature in the system at operation. Such a holder should preferably be accurate enough to hold the laser diode facet X, Y plane orthogonal to the system optical axis, Z.

FIG. 4C shows a housing 30 for mounting the entire laser assembly (the pumping laser diode and the crystals (gain medium and frequency converter)) therein. The housing 30 is preferably made in a molding process to achieve very accurate internal and external diameters D₁ and D₂ in its part 32. The part 32 has holes A, B, and C, holes A serving for inserting glue, hole B serving to allow visual observation of the laser diode (pumping laser) and crystals' facets during mounting of the laser assembly in the housing, and hole C serving for an alignment pin as will be described below.

FIG. 4D shows a crystal unit 33 including resonator cavity 16 (gain medium and frequency converter) mounted in a crystal housing 36 with a thermal conductive sheet 38 being placed on top of the crystal unit 33 (the purpose of which will be described further below). As indicated above, crystals 18 and 20 are bonded to create one unit 33 the two facets of which are used as two Plano mirrors. The housing 36 is thus the so-called “hybrid” housing holding both the gain medium and the frequency converter crystal. The resonator cavity 16 including the gain medium and the frequency converter crystal (e.g. Nd:YVO₄ crystal) is attached to the housing 36. The heat dissipation from the crystal unit 33 should be very good and preferably equal from all crystal four side facets. This will be described more specifically further below.

FIG. 4E shows the entire laser assembly 10 in its exploded view, according to one example of the invention. Laser assembly 10 includes the pumping laser diode unit 22, the assembly housing 30, and hybrid crystal housing 36. The hybrid crystal housing has external diameter D₂ matching the internal diameter of the assembly housing 30 and insertable into housing 30 through its part 32 in a manner allowing its rotation with respect to the housing 30 about optical axis Z and back and forward movement along the Z axis, while the pumping laser diode unit 22 is insertable into housing 30 from its opposite end, by press fit to provide good heat coupling.

FIG. 4F shows another example of the laser assembly, which is generally similar to that of FIG. 4E and further includes a collimating lens 42 and an optical window 44. The window 44 can have IR coating to prevent IR pumping going out of the laser. It also allows for a hermetic seal of the green laser module. Further, a PD can be assembled as a part of the green laser module to allow for cheap and low in real estate real time monitoring of the laser. FIG. 4G illustrates a full green laser assembly 10 in its assembled state.

The general principles of constructing and assembling the laser assembly are associated with the following. As described above, laser diodes output power and wavelength are temperature dependent. Therefore, temperature deviations of the laser diode junction (e.g. affected by the laser diode operation and/or ambient temperature changes) need to be controlled (preferably minimized). Further, the efficiency of the laser diode is lower at higher temperatures. Also, considering the laser assembly utilizing a frequency converter (such as with the green laser) the efficiency of the laser assembly depends on the output wavelength of the laser diode (pumping laser), which in turn depends on the temperature of its active region (junction). Thus, the temperature of the active region of the laser diode needs to be reduced. In order to reduce the temperature and/or the temperature deviations of the active region of the laser diode, heat generated by the laser assembly during operation should be dissipated away from the laser assembly. Good thermal conductivity between the pumping laser diode 12 and its housing 24, between the entire laser diode unit 22 and crystals 18, 20 and the assembly housing 30, as well as good thermal conductivity between the housing 30 and other elements of a system (e.g. optical projector) in which the laser assembly is installed, should be provided. Considering the attachment between the laser diode unit 22 and the assembly housing 30, this can be achieved by inserting the laser diode unit 22 into the housing 30 by a press fit, thus utilizing high thermal conductivity of the metal-to-metal interface. The housing 30 may in turn be inserted into optical chassis of the optical system (e.g. projector) by a press fit, thus achieving a very low thermal resistance interface between the laser assembly housing and the optical chassis.

Turning back to FIG. 4D, the crystal housing 36 is configured to provide symmetrical heat dissipation between the crystal 20 and the crystal housing 36. This is in order to avoid asymmetrical spatial refractive index distribution in the crystal 20, which can influence the laser mode stability and shape. To this end it is preferable that all facets 36A-36C of the crystal would be coupled to the crystal housing 36 with as high as possible thermal conductivity. Keeping in mind that the crystal 20 is to be inserted into an opening in the housing 36 and also that the heat expansion coefficients of the crystal and housing materials are different thus impeding fine attachment between the outer surface of the crystal and the inner surface of the housing all along the contacting surfaces, the above optimized thermal coupling between the crystal 20 and the housing 36 is achieved in the present example by the following: Two facets 36A of the crystal 20 are directly coupled (e.g. using a low viscosity glue) with the respective sides of the inner surface of the housing 36. The low viscosity enables a minimal gap between the crystal 20 and the housing 36 while avoiding stress attributed to thermal expansion of the parts. A thermal conductive sheet 38 (like copper) is placed above facet 36B to be minimally spaced from this facet thus reducing tolerances in a gap between the crystal 20 and the housing 36 and providing heat dissipation from the crystal facet 36B. As for the facet 36C, a gap between this facet and the inner surface of the housing is filled with a thermal glue (i.e. having high thermal conductivity, e.g. indium). Hence, according to the invention, substantially symmetrical heat dissipation is provided from all the facets of the crystal 20 while maintaining very accurate external diameter of the crystal housing. The low heat resistance between the crystal 20 and the crystal housing 36 also helps in decreasing the temperature of the crystal 20, and moreover the crystal housing 36 would induce minimal thermal stress on the crystal 20 over the working temperature range.

To achieve low temperature of the crystal unit 33 low thermal resistivity between the crystal housing 36 and the assembly housing 30 is also needed. The accurate external diameter D₂ of the crystal housing 36 and the accurate internal diameter of assembly housing allows minimal spacing, on the order of for 20-40 μm between them. To achieve good thermal conductivity between the assembly housing 30 and the crystal housing 36, holes A were made in the housing 30, and glue with low viscosity was inserted through these holes (flowing through the holes due to capillary forces) to fill the gap between the two parts. Further, even though glue's thermal conductivity is typically lower than that of metals (housings 36 and 30) the thermal resistance of the interface is kept low due to the small gap between the parts.

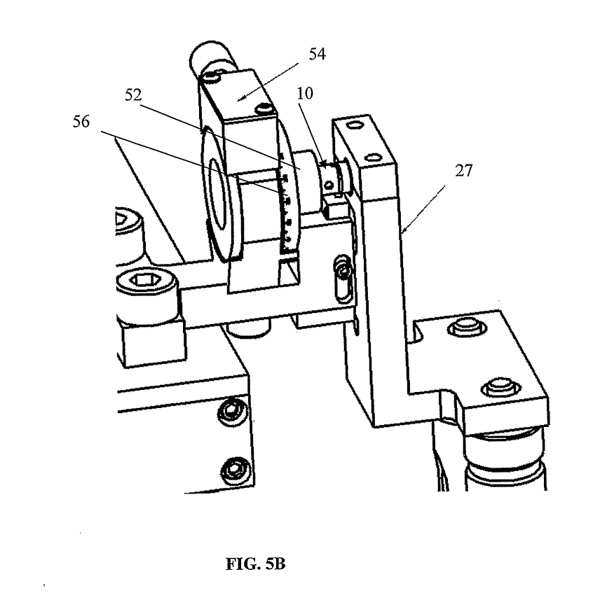

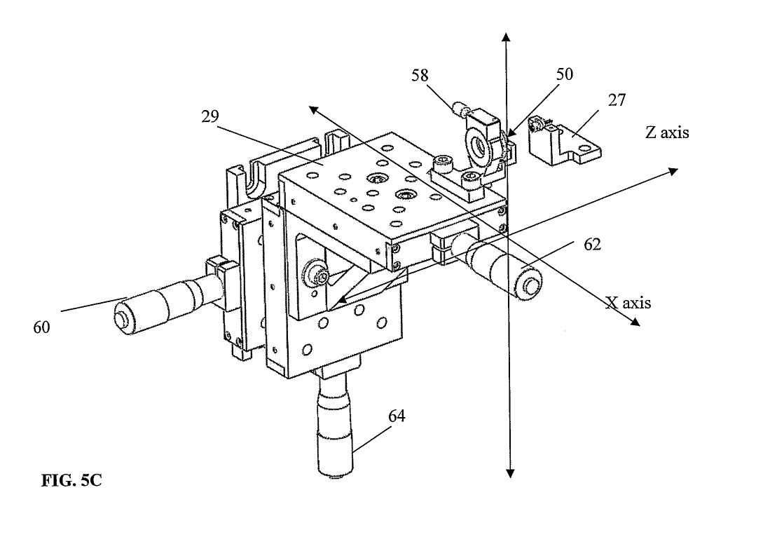

FIGS. 5A to 5C illustrate an example of using a laser assembly of the invention as a light source in an optical system (micro projector in the present example) being mountable onto a jig assembly 48. The latter is used during assembling the laser assembly to provide a desired alignment between the laser diode and the crystals between each other and desired orientation with respect the Z-axis. The jig assembly 48 includes a laser diode holder 27 for controlling the temperature of the laser diode and holding the laser diode mounted (e.g. press fitted) in assembly housing 30 and a support unit 29 for supporting the hybrid housing 36. The hybrid housing 36 is placed on the support such that the gain medium (Nd:YVO₄ crystal medium) faces the laser diode 12. As indicated above, the relative orientation of the laser diode holder 27 and the support stage 29 should be accurate enough to hold the crystal housing x, y plane orthogonal to the optical axis, z.

The arrangement is such that the hybrid housing 36 is mounted in the assembly housing 30 with a possibility of relative movements of one with respect to the other. To this end, the Z-axis support stage 29, a rotational guide assembly 50 and manipulation handles 58, 60, 62 and 64 are used. The movements include a back and forward movement and rotation of the hybrid housing 30 along and about the Z-axis with respect to the assembly housing 30. The guide assembly 50 includes a ring-like holder 52 to which the hybrid housing 36 is attached, and which is in turn fixed to a tuning panel 54, and a bearing 56 enclosing the ring 52 and allowing its rotation (together with the tuning panel 54) about the Z-axis.

Proper alignment between the laser diode 12 (its emitting surface 26) and the resonator 16 (gain medium 18 in the present example, which is in turn properly aligned with the doubler 20 while being bonded thereto) increases the optical power, beam profile and polarization contrast of the laser assembly. In order to get best performance of the laser assembly while having a very fast and cheap assembly process, both the assembly housing 30 and the crystal housing 36 are configured to reduce degrees of freedom from 6 to 2, that is are movable one with respect to the other along theta- and Z-directions. The accurate external diameter D₁ of the crystal housing 36 and accurate internal diameter of the assembly housing 30 allows for about 20-40 μm between them. Such a gap is just enough to allow smooth movement of the two parts relative to each other and thus alignment of Z axis and theta axis. The small gap between the parts also makes it unnecessary to align in the other 4 degrees of freedom x, y, tilt x, tilt y.

The jig assembly is easy to operate to assembly together small-size parts with a desired precise alignment between them. Also, the laser diode housing 24 and the crystal housing 36 are very easy to manufacture and the availability and variability of the housing materials lead to a very cost effective mini laser assembly in terms of mass production.

The pumping laser diode and the crystal housings are typically aligned at least in Z, Θ. In order to reach maximum optical power at the output of the entire laser assembly, the alignment in 6 degrees of freedom can be made. The laser diode and the crystal facets are parallel aligned. This process can be tracked by coaxial camera to verify that for the case where there is no use of coupling lens the crystal and the laser facets don't collide. The laser diode housing and the gain medium crystal housing can be bonded with glue that will not cause a dislocation from the optimal position. For the case where optimization of optical power is not a critical requirement the alignment process can be omitted. Using the z axis translation stage the gain medium crystal can be located close to the laser diode (less than 100 μm). Using the Θ stage, the laser assembly can be optimized for highest output optical power. For assemblies where a specific polarization is of any importance, the optimum output optical power can be set through a polarizer.

It should be noted although not specifically shown that the laser diode is attached to a laser driver (associated with the excitation utility 14A of the control unit 14 in FIG. 1) that provides the exact operation condition, e.g. driving current, frequency and duty cycle. The temperature indicator is connected to the controller (14B in FIG. 1).

1. A method for controlling light output of a laser assembly, which comprises a semiconductor laser diode having an active region and its associated electric current driver, the method comprising controllably operating said electric current driver to excite said active region to induce a certain electric current profile therethrough, said electric current profile corresponding to a desired emission profile from the laser assembly and a desired over heating profile of said active region, while maintaining predetermined temperature range of said active region of the semiconductor laser diode.

2. The method of claim 1, comprising applying over heating to said active region during the emission, said electric current profile corresponding to a pulse mode emission profile and a continuous heating profile.

3. The method of claim 1, comprising applying over heating to said active region in between emission sessions, said electric current profile corresponding to interlaced pulse mode emission and heating profiles.

4. The method of claim 2, wherein the emission pulse has a burst pulse profile.

5. The method of claim 1, wherein the emission of a required power and a required wavelength range from said active region is achieved by exciting the active region with an electrical signal of a value above certain working threshold of the laser assembly.

6. The method of claim 5, wherein said working threshold of the laser assembly corresponds to a lasing threshold of the laser diode.

7. The method of claim 5, wherein said working threshold of the laser assembly corresponds to a pumping threshold of an emitter being pumped by said laser diode.

8. The method of claim 5, wherein said electrical signal of the value above the certain working threshold of the laser assembly is below a certain nominal threshold of the laser assembly.

9. The method of claim 5, wherein said required power and spectrum of the semiconductor laser diode present said light output of the laser assembly.

10. The method of claim 1, comprising either selecting the laser diode or setting initial properties of a given laser diode such that an optimal operating temperature of the active region, at which the laser diode has required output, is higher than ambient temperature or thermal steady state temperature.

11. The method of claim 1, wherein said laser diode is a pumping laser for pumping an external emitter.

12. The method of claim 11, wherein the laser assembly comprises said pumping laser, and a resonator cavity optically pumped by said pumping laser.

13. The method of claim 12, wherein said resonator cavity comprises a gain medium pumped by said pumping laser and a frequency converter crystal operated by light output of the gain medium.

14. The method of claim 11, wherein said laser assembly is configured and operable to produce output of about 808 nm or 880 nm.

15. The method of claim 13, wherein a temperature range of the pumping laser is maintained to produce the wavelength output of the pumping laser corresponding to a maximal absorption of the gain medium.

16. The method of claim 12, comprising providing a desired alignment between the laser diode and the resonator cavity.

17. The method of claim 16, comprising mounting the laser diode and the resonator cavity such that at least one of the laser diode and the resonator cavity is movable with respect to the other along an optical axis of the laser assembly and rotatable about said optical axis.

18. The method of claim 12, comprising providing substantially symmetrical heat dissipation from the resonator cavity.

19. A method for controlling light output of a laser assembly, the method comprising: (i) selecting a semiconductor laser diode having an active region capable of emitting a required spectrum under a certain operating temperature of the active region higher than ambient temperature of environment in which the laser assembly is installed, (ii) controllably operating said electric current driver to excite said active region to induce a certain electric current profile therethrough corresponding to a desired emission profile from the laser assembly and a desired over heating profile of the active region, while maintaining predetermined temperature range of said active region of the semiconductor laser diode.

20. A laser assembly comprising:
a semiconductor laser diode having an active region excitable by an electric current supplied from an associated electric driver for providing emission of light of a required power and spectrum from the laser assembly under a certain operating temperature range of the active region of the laser diode higher than ambient temperature of the laser assembly; and
an excitation utility connectable to said electrical driver and configured and operable for generating an electrical signal corresponding to a certain electric current profile providing a desired emission profile from the laser assembly and a desired over heating profile of the active region, while maintaining predetermined temperature range of said active region of the semiconductor laser diode.

21. The laser assembly of claim 20, wherein said electric current profile corresponds to a pulse mode emission profile and a continuous heating profile.

22. The laser assembly of claim 20, wherein said electric current profile corresponds to interlaced pulse mode emission and heating profiles.

23. The laser assembly of claim 21, wherein the emission pulse has a burst pulse profile.

24. The laser assembly of claim 19, wherein the excitation utility is operable to selectively generate the exciting electrical signal of a value above certain working threshold of the laser assembly, thereby causing emission from said the laser assembly and a certain non zero electrical signal of a value below said working threshold to thereby cause overheating of the active region while preventing emission from the laser assembly.

25. The laser assembly of claim 20, wherein the laser diode is such that an optimal operating temperature range of the active region, at which the laser diode has required output, is higher than ambient temperature or thermal steady state temperature.

26. The laser assembly of claim 20, wherein said working threshold corresponds to a lasing threshold of the laser diode.

27. The laser assembly of claim 20, wherein said laser diode is a pumping laser.

28. The laser assembly of claim 27, wherein said working threshold corresponds to a pumping threshold of an external emitter located in said laser assembly and being pumped by said laser diode.

29. The laser assembly of claim 27, wherein the laser assembly comprises said pumping laser, and a resonator cavity optically pumped by said pumping laser.

30. The laser assembly of claim 29, wherein said resonator cavity comprises a gain medium pumped by said pumping laser and a frequency converter crystal operated by light output of the gain medium.

31. The laser assembly of claim 30, wherein said laser assembly is configured and operable to produce output of about 808 nm or 880 nm.

32. The laser assembly of claim 29, wherein the laser diode and the resonator cavity are mounted in a spaced-apart relationship along an optical axis of the laser assembly with a desired alignment between them.

33. The laser assembly of claim 32, wherein at least one of the laser diode and the resonator cavity is movable with respect to the other along an optical axis of the laser assembly and rotatable about said optical axis.

34. The laser assembly of claim 29, wherein the resonator cavity is mounted in its housing with substantially symmetrical heat dissipation from the resonator cavity.
